(19) United States
(12) Patent Application Publication
(10) Pub. No.: US 2005/0212919 A1
(43) Pub. Date: Sep. 29, 2005

(54) Converter for image input device and mobile device

(76) Inventor: Alex Chou, Chung-Ho City (TW)

Correspondence Address: TRANSPACIFIC LAW GROUP, 617 NORTH DELAWARE STREET, SAN MATEO, CA, 94401, US

(21) Appl. No.: 10/811,433

(22) Filed: Mar. 25, 2004

(51) Int. Cl. H01L 27/00; H04N 5/232

(52) U.S. Cl. 348/211.2

(57) ABSTRACT

This invention discloses a converter for image input device and mobile device, comprising: a control module to control the operation of the image input device and its communication with the mobile device and to set format for data exchange; a data conversion module to convert, according to settings of said control module, data exchanged between the mobile device and the converter, and a data exchange format look-up-table to record all kinds of necessary information relating to data conversion. The invented converter may further comprise a memory module to record a quantity of data, such as image data, and a power module to convert electric power obtained from the mobile device into power useful to the converter and/or the image input device.

### FIELD OF THE INVENTION

The present invention relates to a converter for image input device and mobile device, especially to a converter for digital image input device and mobile handset.

### BACKGROUND OF THE INVENTION

As the multi-media data are widely used in the computer systems, inputting digital image data into the computer system has become a popular application to ordinary users. All kinds of image data input device, such as digital camera, digital video recorder, image scanner, fingerprint capturer, business card reader etc., have been developed. A variety of sources are available for users to input image data into their computer systems.

Among the many kinds of technology relating to inputting digitized image data into the computer system, several communication protocols have been announced and are used in different products. The most popular communication protocols include the USB interface, the PCMCIA interface, the IEEE 1394 interface, the NewCard interface etc. Generally speaking, in one computer system at least one communication interface will be provided to enable the coupling of and the communication with an image input device. On the other hand, a mobile device, such as a personal computer or a personal digital assistance with mobile communication and roaming capability, will also provide such communication interfaces. However, this is not the case in the mobile handset. A mobile handset shall be compact and therefore no such communication interface will be provided in a handset. In a mobile handset provided will be only a particular input/output interface with special specification, depending on the brand name and model number of the handset, to allow peripherals to communicate with the handset. As a result, an image input device is not able to input image data into a mobile device through a general-purposed communication interface.

Technically speaking, it is possible to provide a particular converter to an image input device to enable the data exchange between the image input device and a particular mobile handset. For this purpose, the converter shall comprise: a connector to be plugged by one end of a connection line; the other end of said connection line being provided a connector with particular features and shape to be coupled with the particular input/output slot of the mobile handset. The converter further comprises a data conversion module to transit signals input by the image input device to the mobile handset, to transmit signals generated by the mobile handset to the image input device and to convert digitized image data as captured by the image input device into data with format acceptable by the mobile handset. In addition, it may further comprise an electric power connector to connect particular slot of the mobile handset to obtain electric power from the mobile handset and supply to the image input device.

Such converter for image input device and mobile device is able to convert image data captured by the image input device and supply the converted image data to the mobile device for further processing or for transmission to other computer or communication devices. However, due to the fact that particular converters shall be designed for respective mobile handsets, according to the specification and requirements of the handsets, the converter so designed and fabricated are not universal. A converter suited fore a particular mobile handset is useless to another handset.

### OBJECTIVES OF THE INVENTION

The objective of the present invention is to provide a novel converter for image input device and mobile device to allow communication between the image input device with different mobile devices.

Another objective of this invention is to provide a converter for image input device and mobile device such that the image input device is able to function with different mobile handsets.

### SUMMARY OF THE INVENTION

According to this invention disclosed is a converter for image input device and mobile device, comprising: a control module to control the operation of the image input device and its communication with the mobile device and to set format for data exchange; a data conversion module to convert, according to settings of said control module, data exchanged between the mobile device and the converter; and a data exchange format look-up-table to record all kinds of necessary information relating to data conversion.

The converter for image input device and mobile device of this invention may further comprise a memory module to record a quantity of data, such as image data, and a power module to convert electric power obtained from the mobile device into power useful to the converter and/or the image input device.

### BRIEF DESCRIPTION OF THE DRAWINGS

These and other objectives and advantages of this invention may be clearly understood from the detailed description by referring to the following drawings.

FIG. 1 illustrates the system diagram of the converter for image input device and mobile device of this invention.

FIG. 2 shows factor settings suited for a particular handset as used in the converter for image input device and mobile device of this invention.

### DETAILED DESCRIPTION OF THE INVENTION

Details of the converter for image input device and mobile device of this invention will be described below.

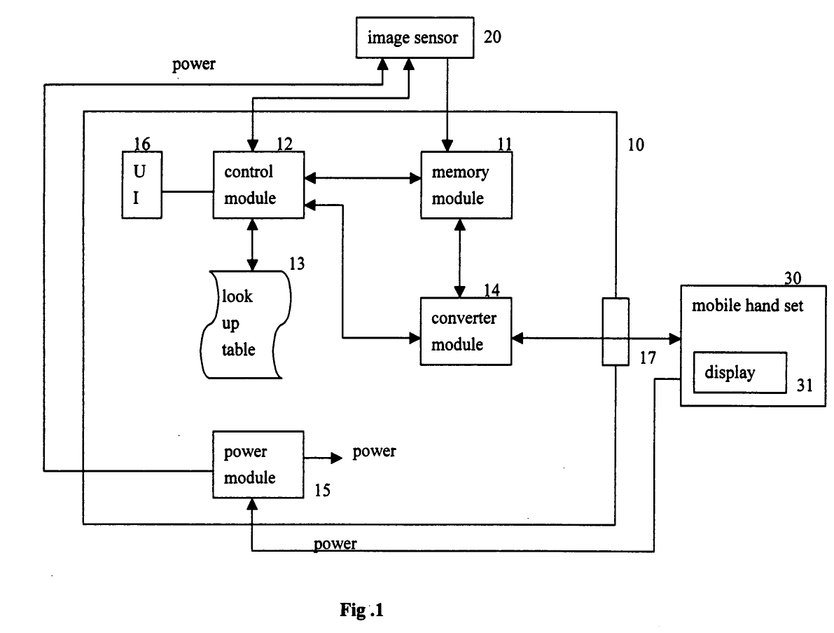

FIG. 1 illustrates the system diagram of the converter for image input device and mobile device of this invention. As shown in this figure, the converter for image input device and mobile device connects a mobile 30 and an image input device. One of the major functions of the converter is to convert data to be exchanged between the image input device and the mobile device. In this figure, only the image sensor 20 of the image input device is shown. This is because the image sensor 20 is the major object to be connected, controlled and data converted by the converter for image input device and mobile device of this invention.

Image input device as applicable in this invention includes digital camera, digital video recorder, image scanner, fingerprint capturer, business card reader etc. The image input device may be any device that is able to capture an image and convert the captured image into a digital format. An image as input is usually a planar image, divided into a plurality of pixels, each pixel representing a component of the image locating at a particular position and being represented by its color (e.g. the three primary colors) and gray level of the color. Of course, other format and form of image data are also applicable in this invention. Suited image sensor includes linear or planar image sensor. The most popular image sensors are CCD (charge coupled device) and CMOS sensor. Other types of sensor that are able to capture planar image may also be used in this invention.

Mobile devices that are applicable in this invention include all kinds of mobile handset, personal digital assistant and personal computer with mobile communication capability. However, as described above, this invention is particularly applicable to mobile handsets. Preferably the mobile device is equipped with a displaying device 31. However, the displaying device 31 is not a necessary component in this invention. A mobile device without a displaying device may be used in this invention.

The converter of this invention comprises: a control module 12 to control the operation of the image sensor and the communication between the converter 10 and the mobile device 32; a data conversion module 14 to convert according to settings of the control module, data to be exchanged between the mobile device 32 and the converter 10; and a data exchange format look-up-table 13 to record all kinds of necessary format information relating to data conversion to be used by the data conversion module 14. The converter 10 of this invention may further comprise a memory module 11 to store a quantity of data for use. In general case, it may be a memory of a large capacity for, such as, at least a frame of planar image, to store planar image data as captured by the image sensor 20 or planar image data received from the mobile device 30. Of course, memory of another format or with other attributes may also be used in this invention.

To consider the data exchange between a mobile device 30 and in image sensor 20, some major concerns include:

Format of image data that are captured by the image sensor, such as resolution, color, gray level, size of image and other factors and data.

Format of control signals of the image sensor and identification of the signals.

Data format acceptable to or used by the mobile device, such as resolution, color, gray level, image of size and other factors and transmission and obtaining of data. Format of signals of the mobile device and identification of the signals.

According to this invention, brand names and model numbers of mobile handset that are available in the market are limited to a certain scope. It is possible to collect factors used in different mobile handsets and make a look-up-table so that a converter may use data in the look-up-table for reference when the converter is connected to a particular mobile handset. As to those brand names or model numbers which factors are not available in the look-up-table, it is possible to add new data to they data exchange format look-up-table through a user interface provided in the mobile device.

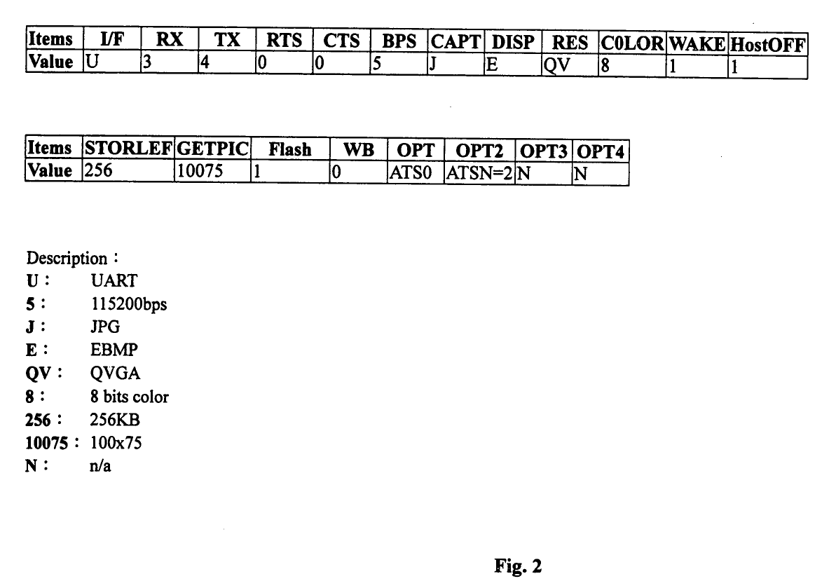

In the converter for image input device and mobile device of this invention, a look-up-table is used to store the above-said and other factors of all available handsets and other factors that is applicable in the image input device. FIG. 2 shows factor settings suited for a particular handset as used in the converter for image input device and mobile device of this invention. As shown in this figure, factors as recorded include: data transmission speed, resolution of image data, color, gray level, size of image etc. Of course, other factors may also be included in the look-up-table 13 of this invention. In the look-up-table 13, the index or indices may be model number of handset, or other information representing brand name or model number existing in the handset.

The control module 12 is able to capture the brand name or model number information of the handset during the initialization period, in which a series of applicable factors are selected from among the data in the look-up-table 13. The selected data are then sent to the data conversion module 14 to be used in the data conversion. In obtaining the brand name or model number information of the mobile handset, it is possible for the converter to automatically obtain the information from the handset during the negotiation period. It is also possible to provide a user interface 16 such that the user can set all these factors. Such technologies are well known to those skilled in the art. Detailed description thereof is thus omitted.

If no user interface 16 is provided in the converter 10, it is also possible to use the existing displaying device 31 and the keyboard (not shown) of the mobile handset 30 to allow the user to set all related factors. In such case, the displaying device and the keyboard is thus omitted. In addition, factors applicable to mobile handsets 30 that are not available in the look-up-table may also be added into the look-up-table 13 through such an interface 16.

In general, the converter for image input device and mobile device of this invention may be actuated upon its connection to the handset 30. At this stage, the converter 10 may actuate the image sensor 20 at the same time. However, it is also possible to use an additional actuator to actuate or turn off the image input device 20 under different conditions. The operation and control of the image input device 20 belong to the known art. Detailed description thereof is thus omitted.

In some embodiments of the present invention, the converter 10 is equipped with a memory 11. The memory can store image data as captured by the image sensor 20. The memory 11 can also store data generated by the mobile device 30. For such purpose, the memory 11 shall have at least a capacity to store a frame of planar image data. Of course, a memory with greater capacity may be used in this invention. A memory with larger capacity of course costs more than that with smaller capacity. The converter for image input device and mobile device may be integrated with the image sensor or even the whole image input device. The communication between the converter and the mobile device 30 may go through the connection means 17. The connection means 17 may be a wired connector or a wireless communication component. If it is a wired connector, it may be a slot to be plugged by a connection line or a signal line. The other end of the signal line is connected to a signal connector of the handset 30. The other end of the signal line is preferably provided with a connector (not shown) that may be coupled to the connector of the handset. If the connection means 17 is a wireless component, it may be any wireless communication component that is able to communicate with the built-in or stand-alone mobile communication component in the mobile handset. Means to transmit the signals may be through infrared, microwave, radio wave or any other known art.

In some embodiments of this invention, a power module 15 is equipped to connect the power or signal connector of the mobile handset 30 and to convert current from the mobile handset 30 to suited current, to be supplied to the converter 10 and/or the image sensor 20.

The converter for image input device and mobile device as described above is able to selectively connect mobile devices of different brand name and model number and input data of image captured by the image input device into the selected mobile device to be displayed, processed or transmitted.

As the present invention has been shown and described with reference to preferred embodiments thereof, those skilled in the art will recognize that the above and other changes may be made therein without departing form the spirit and scope of the invention.

1. A converter for image input device and mobile device, comprising;
a control module to control operation of said image input device and its communication with said mobile device and to set format for data exchange;
a data conversion module to convert, according to settings of said control module, data to be exchanged between said image input device and said mobile device; and
a data exchange format look-up-table to record all kinds of necessary format information for data exchange to be used by said data conversion module.

2. The converter for image input device and mobile device according to claim 1, wherein said mobile device is mobile handset and data recorded in said data exchange format look-up-table include format information relating data exchange that are applicable to a plurality of mobile handsets of know brand names and model numbers.

3. The converter for image input device and mobile device according to claim 1 or 2, wherein said image input device is a digital camera.

4. The converter for image input device and mobile device according to claim 1 or 2, further comprising a memory module to store data including digitalized image data.

5. The converter for image input device and mobile device according to claim 1 or 2, further comprising a memory module to store data including digitalized image data.

6. The converter for image input device and mobile device according to claim 1 or 2, further comprising a user interface allowing users to set factors used in said data conversion module

7. The converter for image input device and mobile device according to claim 1 or 2, further comprising a connection means to establish communication between said converter and said mobile device.

8. The converter for image input device and mobile device according to claim 7, wherein said connection means is wireless communication component.

9. The converter for image input device and mobile device according to claim 7, wherein said connection means comprises a wired number and a connector to be plugged into slot of the mobile device.
